(19) United States
(12) Patent Application Publication
(10) Pub. No.: US 2026/0319041 A1
(43) Pub. Date: Oct. 15, 2026

(54) NUCLEAR MAGNETIC RESONANCE DEVICE

(71) Applicant: 4IR Solutions Ltd., Or-Akiva (IL)

(72) Inventors: Tal Cohen, Herzliya (IL); Mordechai Bercovici, Kiryat Tivon (IL)

(73) Assignee: 4IR Solutions Ltd., Or-Akiva (IL)

(21) Appl. No.: 19/179,891

(22) Filed: Apr. 15, 2025

(51) Int. Cl. G01R 33/44

(52) U.S. Cl. CPC G01R 33/443

(57) ABSTRACT

A method for measuring of a magnetic field generated by a permanent magnet of a nuclear magnetic resonance (NMR) system, the method includes (a) performing NMR measurements using an NMR probe to determine, at multiple points within a three dimensions space in which the permanent magnet is located, oscillating frequencies of a molecule of a fluid located within a housing of the NMR probe; and (b) determining, based on the oscillating frequencies of the molecule at the multiple points, strengths of the magnetic field generated by the permanent magnet at the multiple points.

### BACKGROUND OF THE INVENTION

Nuclear magnetic resonance (NMR) is a physical phenomenon in which nuclei in a strong constant magnetic field are perturbed by a weak oscillating magnetic field (in the near field) and respond by producing an electromagnetic signal with a frequency characteristic of the magnetic field at the nucleus.

This process occurs near resonance, when the oscillation frequency matches the intrinsic frequency of the nuclei, which depends on the strength of the static magnetic field, the chemical environment, and the magnetic properties of the isotope involved.

NMR results from specific magnetic properties of certain atomic nuclei. Nuclear magnetic resonance spectroscopy is widely used to determine the structure of organic molecules in solution and study molecular physics and crystals as well as non-crystalline materials. See—Wikipedia. org.

A production line NMR device is much cheaper than laboratory NMR devices.

The permanent magnets of production line NMR units exhibit an un-homogeneous magnetic field.

Prior art methods for measuring the magnetic field involve using a Gauss meter that is capable to measure the magnetic field along a single axis. In order to measure the magnetic field at a single location there is a need to measure the magnetic fields along three perpendicular axis—at an angular accuracy that does not exceed a few milliradians—therefore introducing angular (and therefore magnetic field measurement) errors as welk as highly complicating the measurement process and making it impractical.

There is a growing need to provide an improved solution for measuring the un-homogeneous magnetic field of a permanent magnets of production line NMR units.

### BRIEF DESCRIPTION OF THE DRAWINGS

The subject matter that is regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawing in which:

FIG. 1 illustrates an example of a permanent magnet of an NMR system and an NMR probe;

FIG. 2 is an example an NMR system and an NMR probe illustrating the size differences between the NMR system and the NMR probe; and

FIG. 3 illustrates an example of a method.

### DETAILED DESCRIPTION OF THE DRAWINGS

The present disclosure relates to methods and systems for measuring magnetic fields generated by permanent magnets in nuclear magnetic resonance (NMR) systems.

In particular, the disclosure provides techniques for characterizing and mapping the magnetic field distribution of permanent magnets used in NMR devices.

NMR systems utilizing permanent magnets may exhibit inhomogeneous magnetic fields that can be challenging to measure accurately. The methods and systems described herein enable precise measurement and characterization of these magnetic fields across three-dimensional space. This capability may allow for improved calibration, compensation, and overall performance of NMR systems.

Performing NMR measurements that at each point provide an accurate sum of the three dimensional magnetic field eliminates alignment required when being limited to single-direction axis measurements of the magnetic field.

The disclosed techniques involve using a compact NMR probe to perform measurements at multiple points within the magnetic field generated by a permanent magnet. By analyzing the oscillating frequencies of molecules within a fluid sample in the probe, the strength and distribution of the magnetic field may be determined with high spatial resolution.

In some cases, the methods described herein may employ machine learning model combined with Finite Elements Analysis software models to process measurement data and derive magnetic field characteristics. The resulting three-dimensional map of the magnetic field may be used to develop compensating measures for addressing field inhomogeneities.

The systems and methods presented in this disclosure may have applications in various fields where precise characterization of magnetic fields is important, such as medical imaging, materials analysis, and quality control in manufacturing processes involving NMR technology.

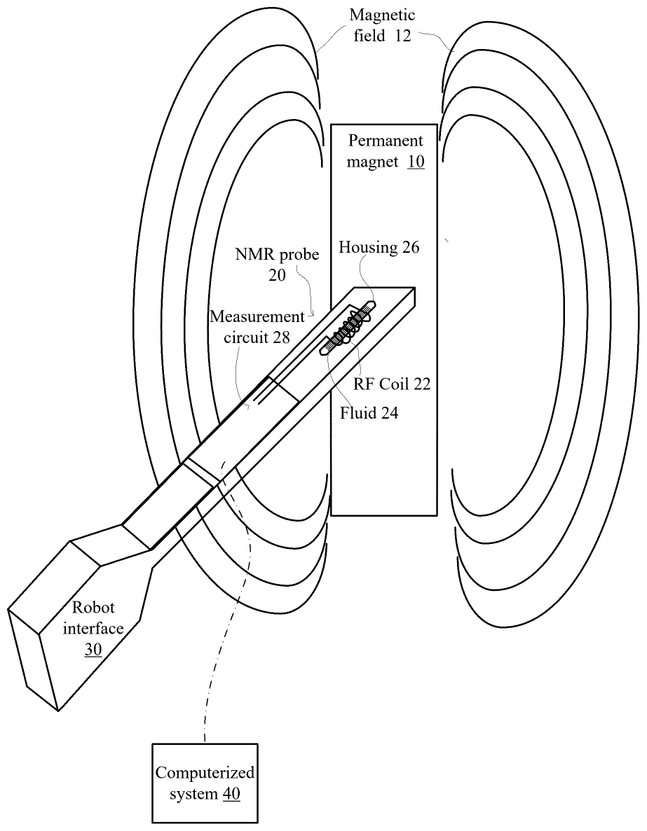

The nuclear magnetic resonance (NMR) system 50 may include a permanent magnet 10 that generates a magnetic field 12. FIG. 1 illustrates a section view of the NMR system 50, showing the permanent magnet 10 and the magnetic field 12 represented by curved field lines extending between opposite sides of the magnet.

In some cases, the permanent magnet 10 may be used in production line NMR units. These production line NMR units may be more cost-effective compared to laboratory NMR devices. However, the permanent magnets 10 in production line NMR units may exhibit an inhomogeneous magnetic field 12, which may present challenges for accurate measurements.

The inhomogeneous nature of the magnetic field 12 generated by the permanent magnet 10 may make precise measurement and characterization difficult. Traditional methods for measuring magnetic fields may not provide sufficient accuracy or spatial resolution to fully capture the variations in field strength across the three-dimensional space surrounding the permanent magnet 10.

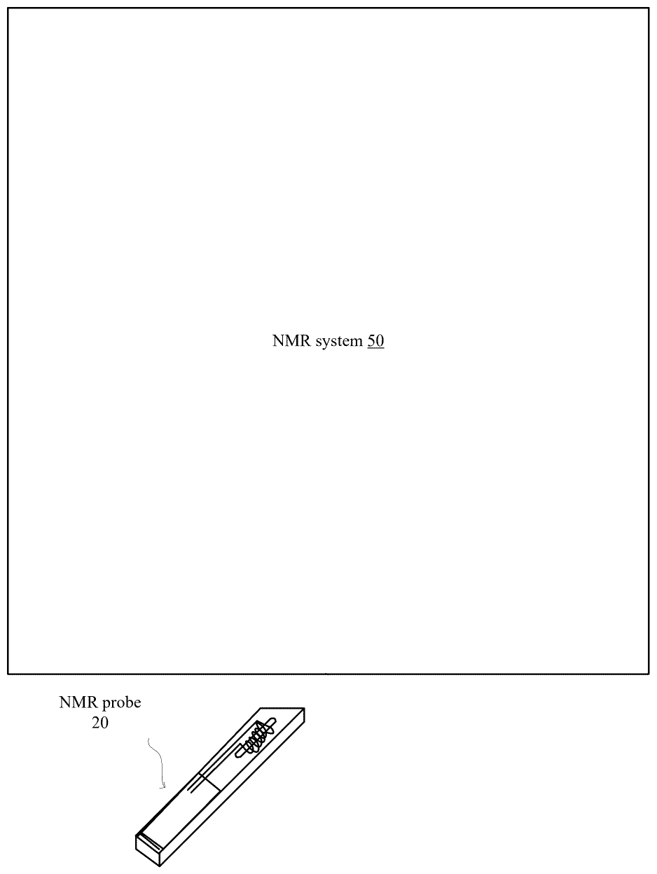

To address these challenges, a method for determining a three-dimensional map of permanent magnet magnetic field inhomogeneity may be employed. This method may involve using an NMR probe 20, as shown in FIG. 1 and FIG. 2, to perform measurements at multiple points within the magnetic field 12. By analyzing the data collected from these measurements, a detailed three-dimensional map of the magnetic field distribution may be created.

The three-dimensional map may provide valuable information about the spatial variations in the strength and direction of the magnetic field 12 generated by the permanent magnet 10. This detailed characterization may allow for a more comprehensive understanding of the magnetic field inhomogeneities present in the NMR system 50.

In some cases, the three-dimensional map of the magnetic field inhomogeneity may be used to determine compensating measures. These compensating measures may be designed to mitigate the effects of the inhomogeneous magnetic field 12 on NMR measurements. By applying appropriate compensations based on the detailed field map, the accuracy and reliability of NMR measurements performed using the NMR system 50 may be improved.

The compensating measures may include physical modifications to the NMR system 50—for example adding elements such as metal elements to the NMR system—especially adding to the elements to permanent magnets. Removing and/or changing existing elements may also be provided. These measures may be tailored to the specific characteristics of the magnetic field 12 as revealed by the three-dimensional map, allowing for more precise and consistent NMR measurements in production line environments.

The NMR probe 20 may be used to perform measurements at multiple points within the magnetic field 12 generated by the permanent magnet 10. FIG. 1 illustrates a section view of the NMR probe 20, showing its key components and structure.

In some cases, the NMR probe 20 may include a housing 26. The housing 26 may be a micro-capillary housing that stores fluid 24. The micro-capillary housing 26 may provide a compact and precise containment for the fluid 24 sample used in NMR measurements.

An RF coil 22 may surround the housing 26. The RF coil 22 may be configured to generate and detect radio frequency signals used in NMR measurements. In some cases, the RF coil 22 may be a radio frequency coil that surrounds the micro-capillary housing 26, allowing for efficient interaction with the fluid 24 contained within.

The NMR probe 20 may also include a measurement circuit 28. The measurement circuit 28 may be configured to provide radio frequency signals to the RF coil 22. These radio frequency signals may induce a changing magnetic field that interacts with magnetic moments of the fluid 24. In some cases, the measurement circuit 28 may be further configured to analyze the interaction between the changing magnetic field and the magnetic moments of the fluid 24.

FIG. 2 illustrates a size comparison between the NMR system 50 and the NMR probe 20. As shown in FIG. 2, the NMR probe 20 may be substantially smaller than the NMR system 50. In some cases, the NMR probe 20 may be smaller by a factor of at least ten compared to the NMR system 50. This compact size may allow for precise positioning and measurement within the magnetic field 12 generated by the permanent magnet 10.

The fluid 24 contained within the housing 26 of the NMR probe 20 may be selected based on the specific measurement requirements. In some cases, the fluid 24 may be water, and the molecule used for NMR measurements may be a hydrogen molecule. Water contains abundant hydrogen atoms, making it a suitable choice for many NMR applications.

The compact structure of the NMR probe 20, including the micro-capillary housing 26, RF coil 22, and measurement circuit 28, may allow for high-resolution measurements of the magnetic field 12 at multiple points in three-dimensional space. This capability may enable detailed characterization and mapping of the magnetic field 12 generated by the permanent magnet 10 in the NMR system 50.

The NMR probe 20 may be positioned and moved within the magnetic field 12 generated by the permanent magnet 10 to perform measurements at multiple points. FIG. 1 illustrates a robot interface 30 connected to the NMR probe 20. The robot interface 30 may facilitate the movement and precise positioning of the NMR probe 20 within the three-dimensional space surrounding the permanent magnet 10.

In some cases, the robot interface 30 may be part of a robotic system designed to move the NMR probe 20 from one point to another within the magnetic field 12.

This automated movement may allow for systematic and repeatable measurements across a defined measurement volume. The robot interface 30 may provide precise control over the position and orientation of the NMR probe 20, enabling high-resolution mapping of the magnetic field 12.

The NMR probe 20 may be carried by a robot connected to the robot interface 30. In some cases, the NMR probe 20 may be significantly smaller than the NMR system 50. For example, the NMR probe 20 may be smaller by a factor of at least ten compared to the NMR system 50. This size difference may be advantageous for achieving high spatial resolution in magnetic field measurements.

The compact size of the NMR probe 20 relative to the NMR system 50 may allow for measurements in confined spaces or regions with steep magnetic field gradients. The robot carrying the NMR probe 20 may be programmed to move the probe through a predefined measurement path, ensuring comprehensive coverage of the magnetic field 12 generated by the permanent magnet 10.

In some cases, the robot interface 30 may communicate with the measurement circuit 28 of the NMR probe 20 to coordinate probe movement with data acquisition. This synchronization may ensure that NMR measurements are taken at precise locations within the magnetic field 12, allowing for accurate mapping of field strength variations.

The ability to move the NMR probe 20 using a robot may enable automated and repeatable measurement sequences. These sequences may involve measuring the oscillating frequencies of molecules in the fluid 24 contained within the housing 26 at multiple points throughout the magnetic field 12. The resulting data may be used to construct a detailed three-dimensional map of the magnetic field strength and distribution around the permanent magnet 10.

The NMR probe 20 may be used to perform NMR measurements at multiple points within the three-dimensional space surrounding the permanent magnet 10. FIG. 1 illustrates the NMR probe 20 positioned within the magnetic field 12 generated by the permanent magnet 10.

In some cases, the measurement circuit 28 of the NMR probe 20 may provide radio frequency signals to the RF coil 22. These signals may induce a changing magnetic field that interacts with magnetic moments of molecules in the fluid 24 contained within the housing 26. The measurement circuit 28 may then analyze the resulting interactions to determine the oscillating frequencies of the molecules at the current position of the NMR probe 20.

The NMR probe 20 may be moved to multiple points within the three-dimensional space using the robot interface 30. At each point, the measurement process may be repeated to determine the oscillating frequencies of the molecules in the fluid 24. This process may result in a collection of oscillating frequency measurements corresponding to different locations within the magnetic field 12.

A computerized system 40 may be connected to the NMR probe 20, as shown in FIG. 1. The computerized system 40 may receive the oscillating frequency data from the measurement circuit 28 and process this data to determine the strengths of the magnetic field 12 at the measured points.

In some cases, the computerized system 40 may employ a first machine learning model to determine the strengths of the magnetic field 12 based on the oscillating frequencies. The first machine learning model may be trained to correlate oscillating frequencies with magnetic field strengths, allowing for accurate estimation of field strength at each measured point.

The computerized system 40 may use the determined magnetic field strengths to create a three-dimensional map of the magnetic field 12 generated by the permanent magnet 10. This map may provide a detailed representation of the magnetic field distribution and any inhomogeneities present in the field.

In some cases, the computerized system 40 may analyze the three-dimensional map to determine compensating measures for permanent magnet magnetic field inhomogeneity. These compensating measures may be designed to mitigate the effects of field inhomogeneities on NMR measurements performed using the NMR system 50.

The computerized system 40 may employ a second machine learning model and/or performing Finite Elements Analysis to determine the compensating measures.

According to an embodiment the Finite Elements Analysis is applied first and may be fine tuned using the second machine learning model.

According to an embodiment the second machine leaning process may be trained to analyze magnetic field distributions and generate appropriate compensation strategies based on the specific characteristics of the field inhomogeneities.

According to an embodiment the second machine leaning process may be trained to analyze results of Finite Elements Analysis and generate appropriate compensation strategies based on the specific characteristics of the field inhomogeneities.

The compensating measures may include physical modifications to the NMR system 50—for example adding elements such as metal elements to the NMR system—especially adding to the elements to permanent magnets. Removing and/or changing existing elements may also be provided. These measures may be tailored to the specific magnetic field distribution of the permanent magnet 10, as characterized by the three-dimensional map.

By employing machine learning models and/or Finite Elements Analysis as well as detailed magnetic field mapping, the described method may enable precise characterization and compensation for magnetic field inhomogeneities in NMR systems using permanent magnets. This approach may improve the accuracy and reliability of NMR measurements in various applications, including production line NMR units.

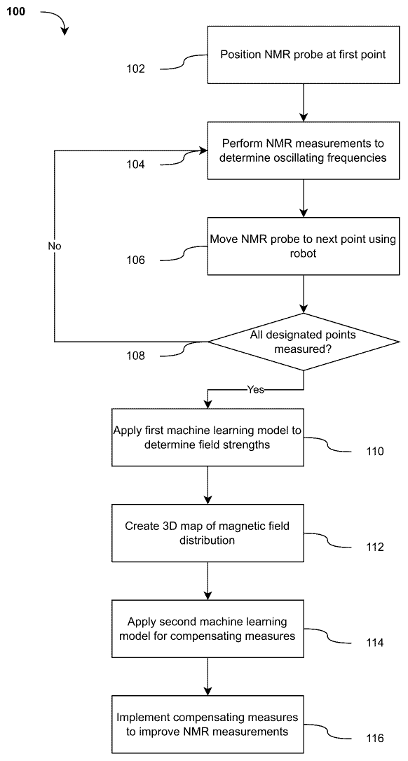

FIG. 3 illustrates a flow chart of a method 100 for measuring a magnetic field generated by a permanent magnet of an NMR system.

The method 100 begins at step 102, where an NMR probe is positioned at a first point within a three-dimensional space surrounding the permanent magnet.

At step 104, NMR measurements are performed using the NMR probe to determine oscillating frequencies of a molecule of a fluid located within a housing of the NMR probe at the current position.

At step 106, the NMR probe is moved to a next point within the three-dimensional space using a robot connected to a robot interface of the NMR probe.

Step 108 checks if the magnetic field in all designated points was measured if yes jumping to step 110—else jumping to step 104—so that steps 104 and 106 are repeated until measurements have been performed at all designated points within the three-dimensional space.

At step 110, a first machine learning model is applied to determine the strengths of the magnetic field at the multiple points based on the measured oscillating frequencies.

At step 112, a three-dimensional map of the magnetic field distribution is created based on the determined field strengths at the multiple points.

At step 114, a second machine learning model and/or Finite Elements Analysis is applied to determine compensating measures for magnetic field inhomogeneity based on the three-dimensional map.

At step 116, the compensating measures are implemented to improve the accuracy and reliability of NMR measurements performed using the NMR system.

The NMR system 50, as illustrated in FIG. 1 and FIG. 2, may integrate various components to measure and characterize the magnetic field 12 generated by the permanent magnet 10. The system may utilize the NMR probe 20, the robot interface 30, and the computerized system 40 to create a comprehensive three-dimensional map of the magnetic field 12 and determine compensating measures for field inhomogeneity.

In some cases, the computerized system 40 may include a non-transitory computer readable medium that stores instructions for performing various functions related to magnetic field measurement and analysis. These instructions may be executed by a processor within the computerized system 40 to control the overall operation of the NMR system 50.

The non-transitory computer readable medium may store instructions for performing NMR measurements using the NMR probe 20. These instructions may direct the measurement circuit 28 to provide radio frequency signals to the RF coil 22, inducing a changing magnetic field that interacts with magnetic moments of molecules in the fluid 24 contained within the housing 26.

In some cases, the non-transitory computer readable medium may store instructions for determining oscillating frequencies of a molecule of the fluid 24 at multiple points within a three-dimensional space surrounding the permanent magnet 10. The computerized system 40 may analyze the data collected by the measurement circuit 28 to extract these oscillating frequencies.

The non-transitory computer readable medium may also store instructions for moving the NMR probe 20 from one point to another using a robot connected to the robot interface 30. This movement may allow for systematic sampling of the magnetic field 12 at various locations within the three-dimensional space.

In some cases, the non-transitory computer readable medium may store instructions for applying a first machine learning model to determine the strengths of the magnetic field 12 based on the measured oscillating frequencies. This model may be trained to correlate oscillating frequencies with magnetic field strengths, enabling accurate estimation of field strength at each measured point.

The non-transitory computer readable medium may further store instructions for determining a three-dimensional map of permanent magnet magnetic field inhomogeneity. This map may be constructed using the field strength data obtained from multiple measurement points, providing a detailed representation of the magnetic field 12 distribution throughout the measurement volume.

In some cases, the non-transitory computer readable medium may store instructions for determining compensating measures for permanent magnet magnetic field inhomogeneity. These compensating measures may be based on the three-dimensional map and may be designed to mitigate the effects of field inhomogeneities on NMR measurements.

The non-transitory computer readable medium may store instructions for applying a second machine learning model and/or with Finite Elements Analysis software to determine the compensating measures. This model may analyze the three-dimensional map of the magnetic field 12 and generate appropriate compensation strategies based on the specific characteristics of the field inhomogeneities.

By integrating these various components and functions, the NMR system 50 may provide a comprehensive solution for measuring, mapping, and compensating for magnetic field inhomogeneities in permanent magnet-based NMR devices. The system may enable precise characterization of the magnetic field 12, potentially improving the accuracy and reliability of NMR measurements in various applications.

In the foregoing detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

Because the illustrated embodiments of the present invention may for the most part, be implemented using microelectronics and/or optical components and circuits known to those skilled in the art, details will not be explained in any greater extent than that considered necessary as illustrated above, for the understanding and appreciation of the underlying concepts of the present invention and in order not to obfuscate or distract from the teachings of the present invention.

Any reference in the specification to a method should be applied mutatis mutandis to a system capable of executing the method.

Any reference in the specification to a system should be applied mutatis mutandis to a method that may be executed by the system.

In the foregoing specification, the invention has been described with reference to specific examples of embodiments of the invention. It will, however, be evident that various modifications and changes may be made therein without departing from the broader spirit and scope of the invention as set forth in the appended claims.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Any arrangement of components to achieve the same functionality is effectively “associated” such that the desired functionality is achieved. Hence, any two components herein combined to achieve a particular functionality may be seen as “associated with” each other such that the desired functionality is achieved, irrespective of architectures or intermedial components. Likewise, any two components so associated can also be viewed as being “operably connected,” or “operably coupled,” to each other to achieve the desired functionality.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

We claim

1. A method for measuring of a magnetic field generated by a permanent magnet of a nuclear magnetic resonance (NMR) system, the method comprising:
performing NMR measurements using an NMR probe to determine, at multiple points within a three dimensions space in which the permanent magnet is located, oscillating frequencies of a molecule of a fluid located within a housing of the NMR probe; and
determining, based on the oscillating frequencies of the molecule at the multiple points, strengths of the magnetic field generated by the permanent magnet at the multiple points.

2. The method according to claim 1, wherein the determining of the strengths of the magnetic field comprising applying a first machine learning model.

3. The method according to claim 1, further comprising determining, based on the strengths of the magnetic field generated by the permanent magnet at the multiple points, compensating measures for compensating for permanent magnet magnetic field inhomogeneity.

4. The method according to claim 3, wherein the determining of the strengths of the magnetic field comprising applying a first machine learning model; and wherein the determining of the compensating measures comprising applying at least one of second machine learning model second machine learning model and Finite Elements Analysis software to determine the compensating measures.

5. The method according to claim 1, further comprising determining a three-dimensional map of permanent magnet magnetic field inhomogeneity.

6. The method according to claim 5, further comprising determining, based on the three dimensional map, compensating measures for compensating for permanent magnet magnetic field inhomogeneity.

7. The method according to claim 1, wherein the performing of the NMR at multiple points comprising moving the NMR probe from one point to another by a robot.

8. The method according to claim 1, wherein the housing is a micro-capillary housing.

9. The method according to claim 1, wherein the NMR probe is carried by a robot from one point to another, wherein the NMR probe is smaller by a factor of at least ten from the first NMR system.

10. The method according to claim 1, wherein the molecule is a hydrogen molecule and the fluid is water.

11. A non-transitory computer readable medium for measuring of a magnetic field generated by a permanent magnet of a nuclear magnetic resonance (NMR) system, the non-transitory computer readable medium stores instructions executable by a processor for:
performing NMR measurements using an NMR probe to determine, at multiple points within a three dimensions space in which the permanent magnet is located, oscillating frequencies of a molecule of a fluid located within a housing of the NMR probe; and
determining, based on the oscillating frequencies of the molecule at the multiple points, strengths of the magnetic field generated by the permanent magnet at the multiple points.

12. The non-transitory computer readable medium according to claim 11, wherein the determining of the strengths of the magnetic field comprising applying a first machine learning model.

13. The non-transitory computer readable medium according to claim 11, further storing instructions for determining, based on the strengths of the magnetic field generated by the permanent magnet at the multiple points, compensating measures for compensating for permanent magnet magnetic field inhomogeneity.

14. The non-transitory computer readable medium according to claim 13, wherein the determining of the strengths of the magnetic field comprising applying a first machine learning model; and wherein the determining of the compensating measures comprising applying at least one of second machine learning model second machine learning model and Finite Elements Analysis software to determine the compensating measures.

15. The non-transitory computer readable medium according to claim 11, further storing instructions for determining a three dimensional map of permanent magnet magnetic field inhomogeneity.

16. The non-transitory computer readable medium according to claim 15, further storing instructions for determining, based on the three dimensional map, compensating measures for compensating for permanent magnet magnetic field inhomogeneity.

17. The non-transitory computer readable medium according to claim 11, wherein the performing of the NMR at multiple points comprising moving the NMR probe from one point to another by a robot.

18. The non-transitory computer readable medium according to claim 11, wherein the housing is a micro-capillary housing.

19. The non-transitory computer readable medium according to claim 11, wherein the NMR probe is carried by a robot from one point to another, wherein the NMR probe is smaller by a factor of at least ten from the first NMR system.

20. The non-transitory computer readable medium according to claim 11, wherein the molecule is a hydrogen molecule and the fluid is water.

21. A nuclear magnetic resonance (NMR) probe, that consists essentially:
a micro-capillary housing that stores fluid;
a radio frequency coil that surrounds the micro-capillary housing;
a measurement circuitry that is configured to provide radio frequency signals to the radio frequency coil to induce a changing magnetic field that interacts with magnetic moments of the fluid, and to analyze the interaction.
